(19) United States
(12) Patent Application Publication
(10) Pub. No.: US 2013/0271532 A1
(43) Pub. Date: Oct. 17, 2013

(54) LIQUID EJECTING HEAD AND PIEZOELECTRIC ELEMENT

(71) Applicant: SEIKO EPSON CORPORATION, Tokyo (JP)

(72) Inventor: Tomohiro SAKAI, Chino (JP)

(73) Assignee: Seiko Epson Corporation, Tokyo (JP)

(21) Appl. No.: 13/851,450

(22) Filed: Mar. 27, 2013

(30) Foreign Application Priority Data
Apr. 13, 2012 (JP) 2012-091810

(51) Int. Cl. H01L 41/18; B41J 2/14

(52) U.S. Cl. CPC H01L 41/18; B41J 2/14201
USPC 347/71; 310/311

(57) ABSTRACT

A piezoelectric layer is formed with a perovskite type oxide at least containing Bi, Ba, Fe, and Ti and when, in 2θ-θ measurement using a two-dimensional detector, an angle formed by a plane including an incident X-ray, a sample, and the center position of the two-dimensional detector and a diffraction line diffracted from the sample is defined as χ and when, in a scattering intensity of the diffraction line obtained by measuring the piezoelectric layer, the integrated intensity in the range of 0°≦χ≦10° and 31°≦2θ≦33° is defined as I₁ and the integrated intensity in the range of 10°≦χ≦20° and 31°≦2θ≦33° is defined as I₂, I₁/I₂ is 2.0 or more.

The entire disclosure of Japanese Patent Application No. 2012-091810, filed Apr. 13, 2012 is incorporated by reference herein.

### BACKGROUND

1. Technical Field

The present invention relates to a piezoelectric element manufactured using a piezoelectric material not containing lead and a liquid ejecting head having the piezoelectric element.

2. Related Art

Heretofore, in order to reduce environmental load, a development of a piezoelectric element using a piezoelectric material not containing Pb (lead) has been advanced. For example, JP-A-2009-252789 and JPA-2009-242229 disclose a piezoelectric element manufactured using a piezoelectric material containing bismuth (Bi) and barium (Ba) in place of Pb.

With the piezoelectric element not containing Pb in a piezoelectric material, a sufficient distortion amount has not been able to obtain in some cases. When a sufficient distortion amount cannot be obtained, the strength of the piezoelectric element is reduced, which poses a problem. Therefore, when the piezoelectric element not containing Pb is put into practical use, there has been a necessity of further securing a distortion amount.

### SUMMARY

An advantage of some aspects of the invention is to increase the performance of a piezoelectric element and a liquid ejecting head containing a lead-free piezoelectric material.

In order to achieve the object, according to a first aspect, the invention provides a liquid ejecting head having a pressure generating chamber communicating with a nozzle opening and a piezoelectric element having a piezoelectric layer and electrodes, in which the piezoelectric layer is formed with a perovskite type oxide at least containing Bi, Ba, Fe, and Ti and when, in 2θ-θ measurement using a two-dimensional detector, an angle formed by a plane including an incident X-ray, a sample, and the center position of the two-dimensional detector and a diffraction line diffracted from the sample is defined as χ and when, in a scattering intensity of the diffraction line obtained by measuring the piezoelectric layer, the integrated intensity in the range of 0°≦θ≦10° and 31°≦2θ≦33° is defined as I₁ and the integrated intensity in the range of 10°≦χ≦20° and 31°≦2θ≦33° is defined as I₂, I₁/I₂ is 2.0 or more.

According to a second aspect, the invention provides a piezoelectric element having a piezoelectric layer and electrodes, in which the piezoelectric layer is formed with a perovskite type oxide at least containing Bi, Ba, Fe, and Ti and when, in 2θ-θ measurement using a two-dimensional detector, an angle formed by a plane including an incident X-ray, a sample, and the center position of the two-dimensional detector and a diffraction line diffracted from the sample is defined as χ and when, in a scattering intensity of the diffraction line obtained by measuring the piezoelectric layer, the integrated intensity in the range of 0°≦χ≦10° and 31°≦2θ≦33° is defined as I₁ and the integrated intensity in the range of 10°≦χ≦20° and 31°≦2θ≦33° is defined as I₂, I₁/I₂ is 2.0 or more.

The present inventors have found that when a ratio of the (110) orientation to random orientation is high in the orientation property of the piezoelectric material, the distortion amount can be increased.

Herein, the ratio of the integrated intensities I₁ and I₂ serve as an index value showing the orientation property in the (110) plane. More specifically, the degree of orientation in the (110) plane in the piezoelectric material is determined as I₂ based on the integrated intensity of the diffraction line obtained by measuring according to the X-ray diffraction method and non-orientation (random orientation) is determined as I₁ based on the integrated intensity in a range of the angle χ different from that of I₂. By determining the ratio of I₂ to I₁, the ratio of the (110) orientation and the random orientation is calculated. The value thus determined can be set to an index value when judging the orientation property of the piezoelectric material capable of increasing the distortion amount.

### BRIEF DESCRIPTION OF THE DRAWINGS

The invention will be described with reference to the accompanying drawings, wherein like numbers reference like elements.

FIGS. 1A and 1B are views explaining a piezoelectric element of the invention.

FIG. 2 is an exploded perspective view in which an ink jet recording head which is an example of a liquid ejecting head is disassembled for convenience.

FIG. 3 is a view explaining the relationship of the angles when performing X-ray analysis.

FIGS. 4A to 4C are cross sectional views illustrating an example of a method for manufacturing a recording head and are vertical cross sectional views along a longitudinal direction of a pressure generating chamber.

FIGS. 5A to 5C are cross sectional views illustrating an example of the method for manufacturing a recording head and are vertical cross sectional views along the longitudinal direction of the pressure generating chamber.

FIG. 6 illustrates the appearance of a recording apparatus (liquid ejecting apparatus) having the recording head described above.

FIG. 7 is a view illustrating the conditions of forming a BF-BT layer in Example 1 and Comparative Example.

FIGS. 8A and 8B are views illustrating two-dimensional images obtained by performing X-ray analysis of Example 1 and Comparative Example.

FIGS. 9A and 9B are views illustrating the hysteresis curves and the butterfly curves of Example 1 and Comparative Example, respectively.

FIG. 10 is a diagram including tables showing changes in the index value Index when changing the conditions of forming piezoelectric elements.

FIGS. 11A and 11B are views showing the butterfly curves of Example 4-2 and Example 4-5.

### DESCRIPTION OF EXEMPLARY EMBODIMENTS

Hereinafter, embodiments of the invention are described. It is a matter of course that the embodiments described below are merely examples of the invention. Outline of piezoelectric element, liquid ejecting head, and liquid ejecting apparatus:

First, examples of a piezoelectric element, a liquid ejecting head, and a liquid ejecting apparatus are described.

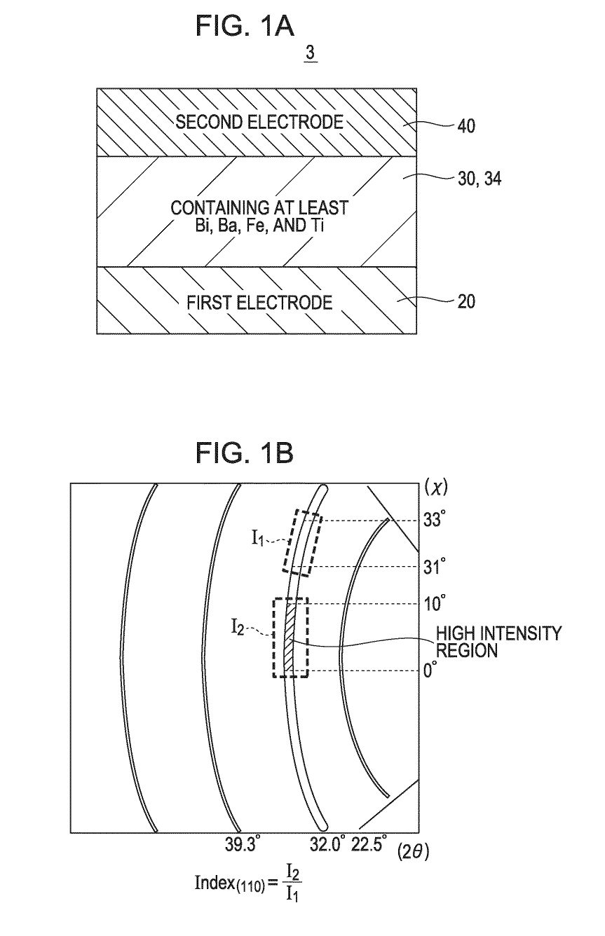

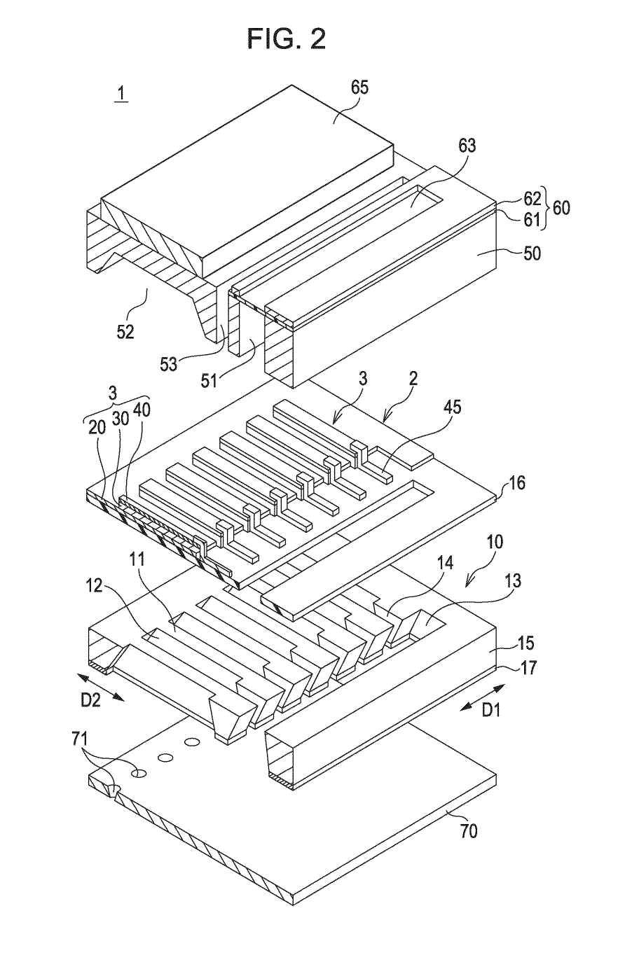

FIGS. 1A and 1B are views explaining a piezoelectric element 3 of the invention. The piezoelectric element 3 illustrated in FIG. 1A has a piezoelectric layer 30 and electrodes (20, 40). A recording head (liquid ejecting head) 1 illustrated in FIG. 2 has the piezoelectric elements 3 and pressure generating chambers 12 which communicate with nozzle openings 71 and in which the pressure is changed by the piezoelectric elements 3. The pressure generating chambers 12 are formed in a silicon substrate 15 of a flow path formation substrate 10. The nozzle openings 71 are formed in a nozzle plate 70. On an elastic film (diaphragm) 16 of the channel formation substrate 10, lower electrodes (first electrodes) 20, the piezoelectric layers 30, and upper electrodes (second electrodes) 40 are laminated in the stated order and the nozzle plate 70 adheres to the silicon substrate 15 in which the pressure generating chambers 12 are formed. A recording apparatus (liquid ejecting apparatus) 200 has the liquid ejecting head as described above.

The positional relationship described in this specification is merely an example for describing the invention and does not limit the invention. Thus, aspects in which the second electrode is disposed at positions other than the position on the first electrode, e.g., bottom, left, right, and the like, are also included in the invention.

The piezoelectric layer 30 has a BF-BT layer 34. The BF-BT layer 34 is formed on the first electrode 20 and contains a perovskite type oxide at least containing Bi (bismuth), Ba (barium), Fe (iron), and Ti (titanium). In the perovskite type oxide, another metal (for example, Mn (manganese)) may be contained in a small proportion in terms of molar ratio while containing Bi, Ba, Fe, and Ti as the main components. Thus, “BF-BT” means containing at least Bi, Ba, Fe, and Ti and also means containing another metal, such as Mn. The BF-BT layer 34 may contain substances (for example, metal oxide) other than the perovskite type oxide. The BF-BT layer 34 can be formed by liquid phase methods, such as a spin coating method and a dip coating method, gaseous phase methods, such as a sputtering method, a PLD method, and an MOCVD method, and the like.

Between the BF-BT layer 34 and the first electrode 20, a buffer layer may be laminated.

Each metal contained in the perovskite type oxide of the BF-BT layer 34 is disposed in the perovskite structure at a site according to the atomic radius. The perovskite type oxide of the BF-BT layer 34 contains at least Bi and Ba in the A site and at least contains Fe and Ti in the B site. Such a perovskite type oxide includes lead-free perovskite type oxides having the compositions represented by the following general formulae.

(Bi,Ba)(Fe,Ti)O_{z} (1)

(Bi,Ba,MA)(Fe,Ti)O_{z} (2)

(Bi,Ba)(Fe,Ti,MB)O_{z} (3)

(Bi,Ba,MA)(Fe,Ti,MB)O_{z} (4)

Herein, MAs in Formulae (2) and (4) are one or more kinds of metallic elements except Bi, Ba, and Pb and MBs in Formulae (3) and (4) are one or more kinds of metallic elements except Fe, Ti, and Pb. Z is 3 as the standard but may be deviated from 3 in a range where the perovskite structure can be achieved. The ratio of the A site elements and the B site elements is 1:1 as the standard but may be deviated from 1:1 in a range where the perovskite structure can be achieved.

The ratio of the number of moles of Bi to the total number of moles of Bi, Ba, and MA can be set to about 50 to 99.9%, for example. The ratio of the number of moles of Ba to the total number of moles of Bi, Ba, and MA can be set to about 0.1 to 50%, for example. The ratio of the number of moles of MA to the total number of moles of Bi, Ba, and MA can be set to about 0.1 to 33%, for example.

The ratio of the number of moles of Fe to the total number of moles of Fe, Ti, and MB can be set to about 50 to 99.9%, for example. The ratio of the number of moles of Ti to the total number of moles of Fe, Ti, and MB can be set to about 0.1 to 50%, for example. The ratio of the number of moles of MB to the total number of moles of Fe, Ti, and MB can be set to about 0.1 to 33%, for example.

The MB element may include Mn and the like. The molar concentration ratio of Mn in the B site constituting metals can be set to about 0.1 to 10%, for example, when the total molar concentration ratio of the B site constituting metals is 100%. When Mn is added, an effect of increasing the insulation of the piezoelectric layer (improving the leak properties) is expected. However, even when Mn is not used, a piezoelectric element having the piezoelectric performance can be formed.

The thickness of the BF-BT layer 34 is not particularly limited and can be set to about 0.2 to 5 μm, for example. The ratio of the thickness of the BF-BT layer 34 to the entire piezoelectric layer 30 can be set to about 0.7 to 0.99, for example.

For the constituent metals of the electrodes (20, 40), one or more kinds of metals, such as Pt (platinum), Au (gold), Ir (iridium), and Ti (titanium), can be used. The constituent metals may be a compound, such as an oxide, may not be combined, may be an alloy, or may be a simple metal and another metal may be contained in a small proportion in terms of molar ratio while containing the metals mentioned above as the main components. The thickness of the electrodes (20, 40) is not particularly limited and can be set to about 10 to 500 nm, for example.

The BF-BT layer 34 is formed by a process including a BF-BT application process and a BF-BT layer formation process.

In the BF-BT application process, a BF-BT precursor solution at least containing Bi, Ba, Fe, and Ti is applied in the shape of a film to the surface of the lower electrode 20. The BF-BT precursor solution may contain another metal (for example, about 0.1 to 10% of Mn) in a small proportion in terms of molar ratio while containing Bi, Ba, Fe, and Ti as the main components. For metal salts contained in the precursor solution, organic acid salts, such as 2-ethyl hexanoic acid salt and acetic acid salt, and the like can be used. The precursor solution includes a solution in which the metal salts are dissolved in a solvent, a sol in which the metal salts are dispersed in a dispersion medium, and the like. For the solvent and the dispersion medium, those containing organic solvents, such as octane, xylene, and combinations thereof, and the like can be used. The application of the precursor solution can be carried out by the liquid phase methods mentioned above, such as a spin coating method. The thickness of the coating film is not particularly limited and can be set to about 0.1 μm, for example.

In the BF-BT layer formation process, the applied BF-BT precursor solution is crystallized to thereby form the BF-BT layer 34 containing a perovskite type oxide. The BF-BT layer formation process further includes a drying process, a degreasing process, and a firing process. In the firing process, the precursor solution is fired at a predetermined firing temperature. Since the crystallization temperature of the piezoelectric layer 30 containing the perovskite type oxide at least containing Bi, Ba, Fe, and Ti is higher than 550° C. and lower than 900° C., for example, the firing temperature is set in this range.

Heretofore, it has been known that the distortion amount of a piezoelectric element containing a lead-free piezoelectric material is smaller than that of a piezoelectric element containing a piezoelectric material containing Pb. The distortion amount in the piezoelectric element can be shown also using a butterfly curve.

The preset inventors have discovered that the distortion amount can be increased by increasing the orientation property in the (110) plane in the BF-BT layer 34 in the lead-free piezoelectric element. The present inventors have invented a technique of showing the orientation property in the (110) plane as an index based on the integrated intensity of the diffraction line when performing X-ray analysis as illustrated in FIG. 1B.

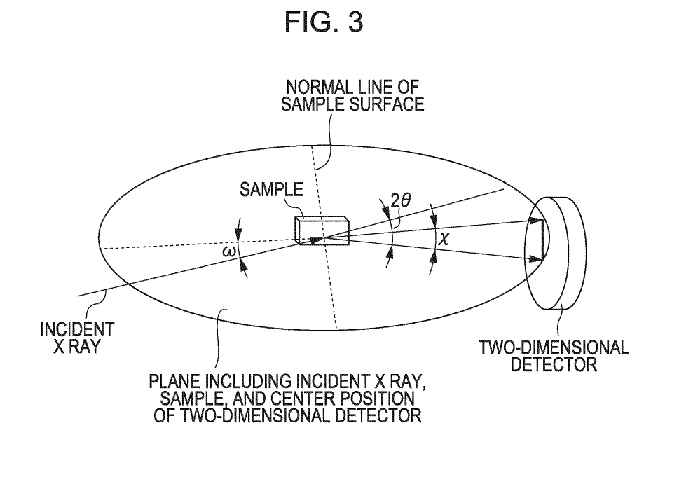

FIG. 3 is a view explaining the relationship of the angles when performing the X-ray analysis. Herein, as illustrated in FIG. 3, ω is an angle formed by an incident X-ray and a sample. 2θ is an angle formed by an X-ray diffracted into a plane perpendicular to a sample and an incident X-ray. χ is an angle formed by a plane constituted by an incident X-ray, the sample, and the center position of a two-dimensional detector and a diffraction line diffracted from the sample. When performing the X-ray analysis, the measurement of the diffraction line is performed while maintaining that the angles of 2ω and 2θ are the same. The measurement of the direction of the angle χ includes, in addition to the case using a two-dimensional detector, a case using a one-dimensional detector and a case using a 0-dimensional detector, and further a case of measuring the direction of the angle χ by changing the detectors to the χ direction. As an example maintaining the relationship of the sample, the X-ray, and the diffraction line, a known apparatus, such as a goniometer, is used.

In a two-dimensional image illustrated in FIG. 1B, the horizontal axis is 2θ and the vertical axis is χ. In this image, diffraction lines formed by the X-rays diffracting at the (100) plane, the (110) plane, and the (111) plane of the BF-BT layer 34 are formed, in the regions where 2θ is 22.5°, 2θ is 32.0°, and 2θ is 39.3°, respectively. The intensity of the diffraction lines can be determined based on the counted number per unit time (count per second) of the detection points (spots) to be counted. For example, it can be considered that a region where the spots are concentrated has high intensity. On the contrary, it can be considered that a region where the spots are not concentrated has low intensity. Thus, the intensity of the diffraction line can be indicated by the integrated value obtained by integrating of the value obtained by counting the diffraction lines by the detector by a computer and the like.

Herein, as illustrated in FIG. 1B, the spots of the diffraction line at 2θ=32.0° are distributed with a higher density as compared with the diffraction lines at other 2θ angles (θ=22.5°, 39.3°), which shows that the (110) orientation degree is high. Also in the diffraction line at 2θ=32.0° showing such a (110) orientation, the spot distribution in the range of χ=0° to 10° is concentrated as compared with other ranges, which shows that the intensity in the range of 0°≦χ≦10° is the highest. More specifically, it is found that, in the diffraction line at 2θ=32.0°, a high orientation degree region and a random orientation region are co-existent according to the range of χ.

The present inventors show the degree of orientation as an index using the following Expression (5) based on the orientation property of the piezoelectric material shown above.

$${Index}_{( 110 )} = \frac{{I}_{2}}{{I}_{1}} \qquad ( 5 )$$

In the expression, the Index₍₁₁₀₎ is an index value showing the orientation property in the (110) plane. I₁ shows the integrated intensity in the range of 31°≦2θ≦33° and 10°≦χ≦20° in the diffraction line at 2θ=32.0°. I₂ shows the integrated intensity in the range of 31°≦2θ≦33° and 0°≦χ≦10° in the diffraction line at 2θ=32.0°. The integrated intensity is a value obtained by integrating the detection point of the diffraction line by the χ direction. With respect to the index value Index₍₁₁₀₎, a larger value indicates that the (110) orientation is higher and, on the contrary, a value closer to 1.0 indicates that the orientation is random orientation.

It has been found in Expression (5) above that, in the BF-BT layer 34 where the value of the index value Index₍₁₁₀₎ indicating the orientation property is 2.0 or more, the distortion amount is increased. More specifically, it has been found that, in the piezoelectric element containing the BF-BT layer 34 in which Index₍₁₁₀₎≧2.0 is established, the distortion amount is increased as compared with former piezoelectric elements not containing Pb.

By judging the orientation property of a certain plane using the Index₍₁₁₀₎, the following merits are obtained. More specifically, since the orientation property is judged only in the (110) plane, the influence of samples other than the piezoelectric material can be excluded. More specifically, when there is a sample showing the same orientation whose degree of orientation is the same as the degree of orientation to be contrasted in samples other than the piezoelectric material in a case of calculating the degree of orientation using the integrated intensity of the (110) plane and the integrated intensity of another plane (for example, (100) plane) according to the Lotgering method and the like, the integrated intensity of the sample is added to the integrated intensity of the plane to be contrasted, so that a correct value of the intensity ratio is not obtained in some cases. For example, platinum shows a strong peak at 2θ=39.3° ((111) plane). Thus, when the integrated intensities of the (110) plane and the (111) plane are compared, a correct intensity ratio cannot be obtained under the influence of a platinum electrode in some cases. On the other hand, in the judgment of the orientation property using the Index₍₁₁₀₎, since the orientation property is judged from the integrated intensity of only the (110) plane, the judgment is not affected by other samples mentioned above. It is a matter of course that the same applies to an electrode of Ir (iridium) or the like in which the (110) orientation property is high. Example of method for manufacturing piezoelectric element and liquid ejecting head:

Next, a method for manufacturing a piezoelectric element and a liquid ejecting head having such a BF-BT layer is described.

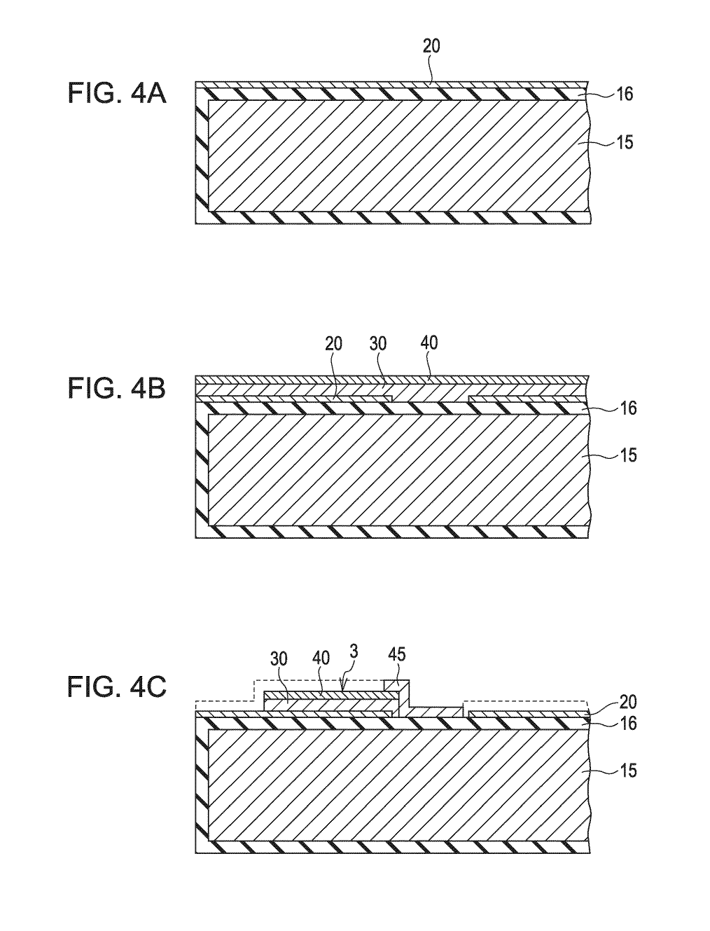

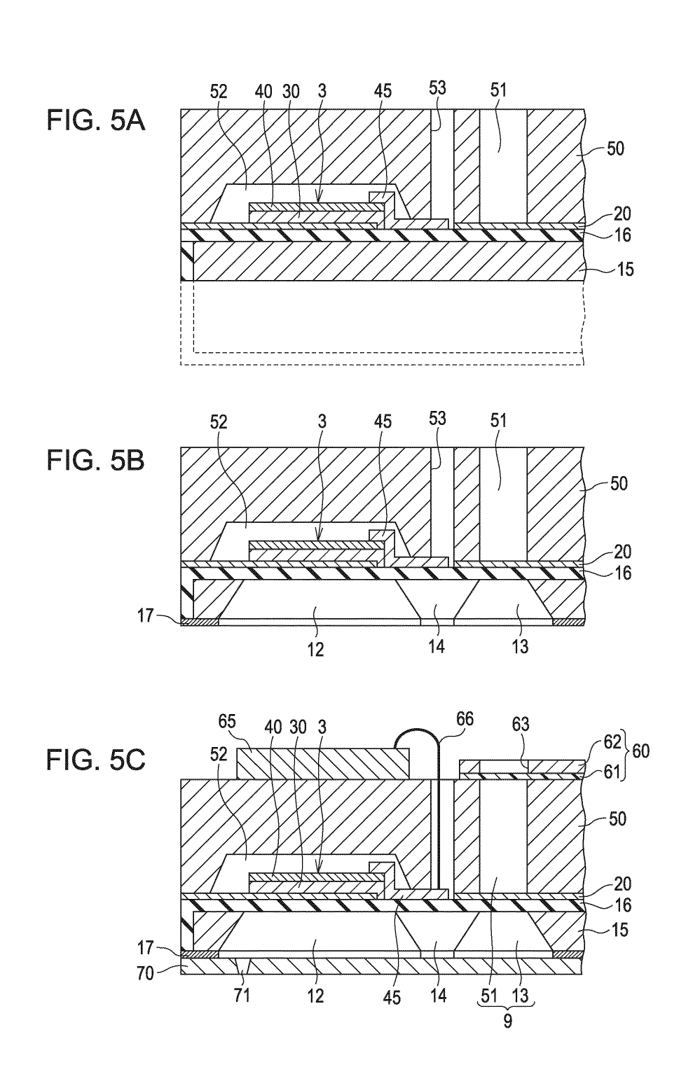

FIG. 2 is an exploded perspective view in which an ink jet recording head 1 which is an example of a liquid ejecting head is disassembled for convenience. FIGS. 4A to 5C are cross sectional views for illustrating an example of a method for manufacturing a recording head and are vertical cross sectional views along a longitudinal direction D2 of a pressure generating chamber 12. Each layer constituting the recording head 1 may be bonded and laminated or integrally formed by denaturing the surface of a material which is not separated.

The channel formation substrate 10 can be formed from a silicon single crystal substrate and the like. The elastic film 16 can be integrally formed with the silicon substrate 15 by thermally oxidizing one surface of the silicon substrate 15 having a relatively large film thickness of, for example, about 500 to 800 μm and having high rigidity in a diffusion furnace of about 1100° C. or the like and can be constituted of silicon dioxide (SiO₂) and the like. The thickness of the elastic film 16 is not particularly limited insofar as elasticity is exhibited and can be set to about 0.5 to 2 μm, for example.

Subsequently, as illustrated in FIG. 4A, the lower electrode 20 is formed on the elastic film 16 by a sputtering method or the like. In the example illustrated in FIG. 4B, the lower electrode 20 is formed, and then patterned. The thickness of the lower electrode 20 is not particularly limited and can be set to about 50 to 500 nm, for example. As an adhesion layer or a diffusion preventing layer, layers, such as a titanium nitride aluminum (TiAlN) film, an Ir film, an iridium oxide (IrO) film, and a zirconium dioxide (ZrO₂) film, may be formed on the elastic film 16, and then the lower electrode 20 may be formed on the layers.

Subsequently, the BF-BT precursor solution described above is applied to the surface containing the lower electrode 20 (BF-BT application process), and then the applied BF-BT precursor solution is crystallized to thereby form the BF-BT layer 34 containing a perovskite type oxide (BF-BT layer formation process). When the film of the BF-BT precursor solution is heated at a temperature equal to or higher than the crystallization temperature of the perovskite type oxide, the BF-BT layer 34 containing the perovskite type oxide and having a thin film shape is formed. Preferably, the film is dried by heating to about 140 to 190° C., for example (drying process), the film is degreased by heating to about 300 to 400° C., for example (degreasing process), and then the film is crystallized by heating the film to about 550 to 850° C., for example (firing process).

In order to increase the thickness of the piezoelectric layer 30, the combination of the application process, the drying process, the degreasing process, and the firing process may be performed two or more times. In order to reduce the firing process, the firing process may be performed after performing the combination of the application process, the drying process, and the degreasing process two or more times. Furthermore, the combination of these processes may be performed two or more times.

The thickness of the piezoelectric layer 30 to be formed is not particularly limited in a range where an electromechanical conversion action is exhibited and can be set to about 0.2 to 5 μm, for example.

For a heating device for performing the drying process and the degreasing process described above, a hot plate, an infrared lamp annealing apparatus for heating by irradiation with an infrared lamp, and the like can be used. For a heating device for performing the firing process, an infrared lamp annealing apparatus and the like can be used. Preferably, the temperature increase rate may be set to 50° C./sec or more using an RTA (Rapid Thermal Annealing) method or the like.

After forming the piezoelectric layer 30, the upper electrode 40 is formed on the piezoelectric layer 30 by a sputtering method or the like as illustrated in FIG. 4B. The thickness of the upper electrode 40 is not particularly limited and can be set to about 20 to 200 nm, for example. In the example illustrated in FIG. 4C, after forming the upper electrode 40, the piezoelectric layer 30 and the upper electrode 40 are patterned in a region facing each pressure generating chamber 12, thereby forming the piezoelectric element 3.

In general, one electrode of the piezoelectric elements 3 is used as a common electrode and the other electrode and the piezoelectric layer 30 are patterned for each pressure generating chamber 12, thereby constituting the piezoelectric element 3. In the piezoelectric element 3 illustrated in FIGS. 2 and 4A to 4C, the lower electrodes 20 serve as a common electrode and the upper electrodes 40 serve as individual electrodes.

Thus, the piezoelectric element 3 having the piezoelectric layer 30 and the electrodes (20, 40) is formed, and a piezoelectric actuator 2 having the piezoelectric element 3 and the elastic film 16 is formed.

Subsequently, as illustrated in FIG. 4C, a lead electrode 45 is formed. For example, a metal layer is formed on the entire surface of the channel formation substrate 10, and then patterned for each piezoelectric element 3 through a mask pattern containing a resist or the like, thereby providing the lead electrode 45. To each upper electrode 40 illustrated in FIG. 2, the lead electrode 45 extended onto the elastic film 16 from the vicinity of the end portion at the side of an ink supply path 14 is connected.

The lower electrode 20, the upper electrode 40, and the lead electrode 45 can be formed by a sputtering method, such as a DC (direct current) magnetron sputtering method, or the like. The thickness of each layer can be adjusted by changing an applied voltage of a sputtering apparatus and a sputtering treatment time.

Subsequently, as illustrated in FIG. 5A, a protective substrate 50 in which a piezoelectric element holding portion 52 and the like are formed beforehand is bonded onto the channel formation substrate 10 with an adhesive, for example. For the protective substrate 50, a silicon single crystal substrate, glass, a ceramic material, and the like can be used, for example. The thickness of the protective substrate 50 is not particularly limited and can be set to about 300 to 500 μm, for example. A reservoir portion 51 penetrating in the thickness direction of the protective substrate 50 constitutes a reservoir 9 serving as a common ink chamber (liquid chamber) with a communication portion 13. The piezoelectric element holding portion 52 provided in a region facing the piezoelectric element 3 has a space large enough not to inhibit the movement of the piezoelectric element 3. Into a penetration hole 53 of the protective substrate 50, the vicinity of the end portion of the lead electrode 45 drawn out from each piezoelectric element 3 is exposed.

Subsequently, the silicon substrate 15 is polished to reach a certain thickness, and then wet-etched using with fluonitric acid to thereby set the thickness of the silicon substrate 15 to a predetermined thickness (for example, about 60 to 80 μm). Subsequently, as illustrated in FIG. 5B, a mask film 17 is newly formed on the silicon substrate 15, and then patterned into a predetermined shape. For the mask film 17, silicon nitride (SiN) and the like can be used. Subsequently, the silicon substrate 15 is anisotropically etched (wet etched) using an alkaline solution, such as KOH. Thus, the pressure generating chambers 12 defined by a plurality of partitions 11, a plurality of liquid flow paths each having the narrow ink supply path 14, and the communication portion 13 which is a common liquid flow path connected to each ink supply path 14 are formed. The liquid flow paths (12, 14) are disposed in the width direction D1 which is a short-side direction of the pressure generating chambers 12.

The pressure generating chambers 12 may be formed before the formation of the piezoelectric element 3.

Subsequently, unnecessary portions of the peripheral portions of the flow path formation substrate 10 and the protective substrate 50 are cut by dicing and removed. Subsequently, as illustrated in FIG. 5C, a nozzle plate 70 is bonded to the surface on the side opposite to the surface where the protective substrate 50 is provided of the silicon substrate 15. For the nozzle plate 70, glass ceramics, a silicon single crystal substrate, stainless steel, and the like can be used and is fixed to the opening surface side of the flow path formation substrate 10. For the fixation, an adhesive, a hot-melt film, and the like can be used. In the nozzle plate 70, the nozzle openings 71 are formed each of which communicates with the vicinity of the end portion on the side opposite to the ink supply path 14 of each pressure generating chamber 12. Thus, the pressure generating chambers 12 communicate with the nozzle openings 71 which discharge liquid.

Subsequently, a compliance substrate 60 having a sealing film 61 and a fixation substrate 62 is bonded onto the protective substrate 50, and then divided into a predetermined chip size. The sealing film 61 contains a material having low rigidity and flexibility, such as a polyphenylene sulfide (PPS) film having a thickness of about 4 to 8 μm, and the like and seals one surface of the reservoir portion 51. The fixation substrate 62 contains a hard material, such as metal, e.g., stainless steel (SUS) having a thickness of about 20 to 40 μm, for example, in which a region facing the reservoir 9 forms an opening 63.

Onto the protective substrate 50, a drive circuit 65 for driving the piezoelectric elements 3 disposed in parallel is fixed. For the drive circuit 65, a circuit substrate, a semiconductor integrated circuit (IC), and the like can be used. The drive circuit 65 and the lead electrode 45 are electrically connected through a connection wiring 66. For the connection wiring 66, a conductive wire, such as a bonding wire, and the like can be used.

Thus, the recording head 1 is manufactured.

In the recording head 1, ink is taken from an ink introduction port connected to an external ink supply unit which is not illustrated, and then the inside of a space from the reservoir 9 to the nozzle opening 71 is filled with the ink. When a voltage is applied between the lower electrode 20 and the upper electrode 40 in each pressure generating chamber 12 according to a recording signal from the drive circuit 65, ink droplets are discharged from the nozzle opening 71 due to deformation of the piezoelectric layer 30, the lower electrode 20, and the elastic film 16.

The recording head may be configured so that the lower electrodes may be used as a common electrode and the upper electrodes may be used as individual electrodes, may be configured so that the upper electrodes may be used as a common electrode and the lower electrodes may be used as individual electrodes, or may be configured so that the lower electrodes and the upper electrodes are used as a common electrode and individual electrodes are provided between both the electrodes.

### Liquid Ejecting Apparatus:

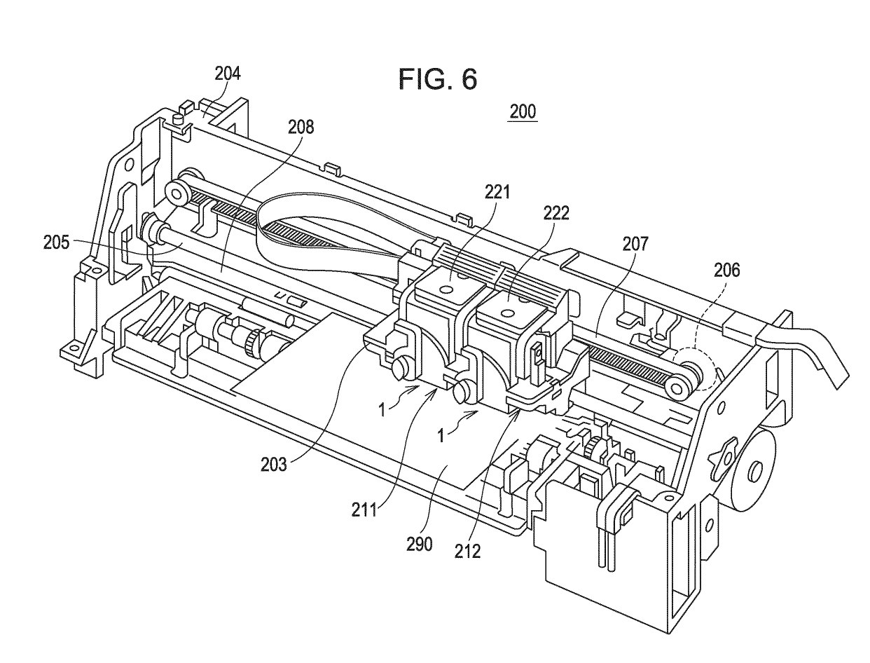

FIG. 6 illustrates the appearance of a recording apparatus (liquid ejecting apparatus) 200 having the recording head 1 described above. By installing the recording head 1 in recording head units 211 and 212, the recording apparatus 200 can be manufactured. In the recording apparatus 200 illustrated in FIG. 6, each of the recording head units 211 and 212 is provided with the recording head 1 and ink cartridges 221 and 222 which are external ink supply units are detachably attached to the recording head units 211 and 212, respectively. A carriage 203 carrying the recording head units 211 and 212 is provided in such a manner that the carriage 203 can move back and force along a carriage shaft 205 attached to an apparatus bod 204. When the driving force of the drive motor 206 is transmitted to the carriage 203 through a plurality of gears which are not illustrated and a timing belt 207, the carriage 203 moves along the carriage shaft 205. A recording sheet 290 fed by a paper feed roller and the like which are not illustrated is transported onto a platen 208, and then printing is performed by ink supplied from the ink cartridges 221 and 222 to be discharged from the recording heads 1.

### EXAMPLES

Hereinafter, Examples are described but the invention is not particularly limited to Examples described below.

### Production of Lower Electrode Formation Substrate

A single crystal silicon (Si) substrate oriented in (100) was heated in a diffusion furnace to thermally oxidize the surface thereof, thereby forming a silicon dioxide (SiO₂) film having a film thickness of 1200 nm on the surface of the Si substrate. Next, a titanium (Ti) film having a film thickness of 40 nm was formed on the SiO₂ film by an RF (Radio Frequency) magnetron sputtering method, and then thermally oxidized, whereby a titanium oxide (TiOₓ) film was formed. Further, a platinum (Pt) film (lower electrode 20) which was oriented in the (111) plane and had a thickness of 100 nm was formed on the titanium oxide film by an RF magnetron sputtering method.

### Production of BF-BT Precursor Solution

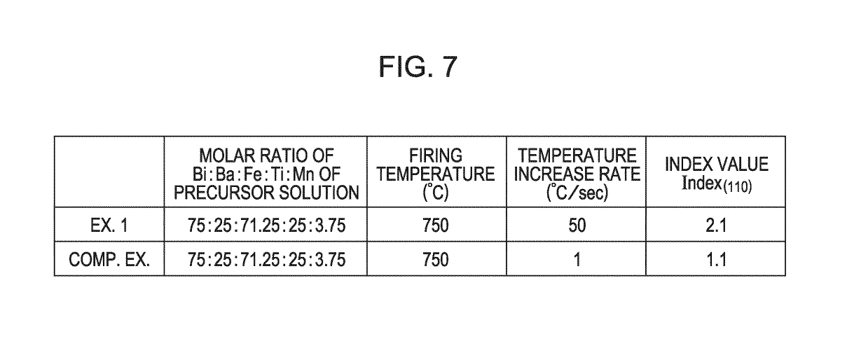

FIG. 7 is a view illustrating the conditions for forming BF-BT layers in Example and Comparative Example. First, precursor solutions were prepared under the conditions shown in FIG. 7. 2-ethyl hexanoic acid salt was used as precursor materials of metallic elements of Bi, Ba, Fe, Ti, and Mn. The molar concentration ratio of the metals to be dissolved was set to Bi:Ba:Fe:Ti:Mn=75:25:71.25:25:3.75 as Example 1. A target perovskite type oxide of the BF-BT layer is (Bi, Ba)(Fe, Ti, Mn)O_{z}. For the solvent, n-octane was used.

### Production of BF-BT Layer Formation Substrate

The BF-BT precursor solution was added dropwise onto a buffer layer of a buffer layer formation substrate, the substrate was rotated at 3000 rpm, whereby a BF-BT precursor film was formed by a spin coating method (BF-BT application process). Next, the substrate was placed on a hot plate, heated to 180° C., and then dried for 2 minutes (drying process). The substrate after drying was heated to 450° C., and then degreasing was performed for 2 minutes (degreasing process). Each of the drying process and the degreasing process was further performed one more time.

The substrate after degreased was fired at 750° C. for 5 minutes in an oxygen environment by an RTA (Rapid Thermal Annealing) apparatus (firing process). The temperature increase rate at this time was set to 50° C./sec. Then, the BF-BT application process, the drying process, and the degreasing process were repeated 4 times, and then the substrate was fired at 750° C. in an oxygen environment by an RTA apparatus. By repeating the combination of “four times of the combination of the BF-BT application process, the drying process, and the degreasing process” and “the firing process” twice, the BF-BT layer having 10 layers was formed by the spin coating process. More specifically, a piezoelectric layer having a total thickness of 750 nm was formed by performing the application of the BF-BT thin films 10 times.

### Comparative Example

As Comparative Example, a BF-BT precursor solution in which the molar concentration ratio of metals was Bi:Ba:Fe:Ti:Mn=75:25:71.25:25:3.75 was used, the firing temperature was set to 750° C., and the temperature increase rate was set to 1° C./sec. The conditions other than the conditions above were the same as those of Example 1.

### Production of Piezoelectric Element

In each Example and Comparative Example 1, a 100 nm thick platinum thin film (upper electrode 40) was formed on the piezoelectric layer of the BF-BT layer formation substrate by a sputtering method, and then fired at 750° C. for 5 minutes in an oxygen environment by an RTA apparatus, whereby a piezoelectric element was formed.

### X-Ray Analysis

In order to analyze the orientation property of Example 1 and Comparative Example, X-ray analysis was performed. For the X-ray analysis, a D8Discover manufactured by Bruker AXS was used and CuKα ray was used as the X-ray source. For a detector, a two-dimensional detector (Hi-STAR) was used. As the measurement conditions, a 50 μmφ collimator was used as a collimator on the side of the X-ray source, the voltage of the X-ray source was set to 50 kV, the current thereof was set to 100 mA, and the distance from the samples to the two-dimensional detector was set to 15 cm.

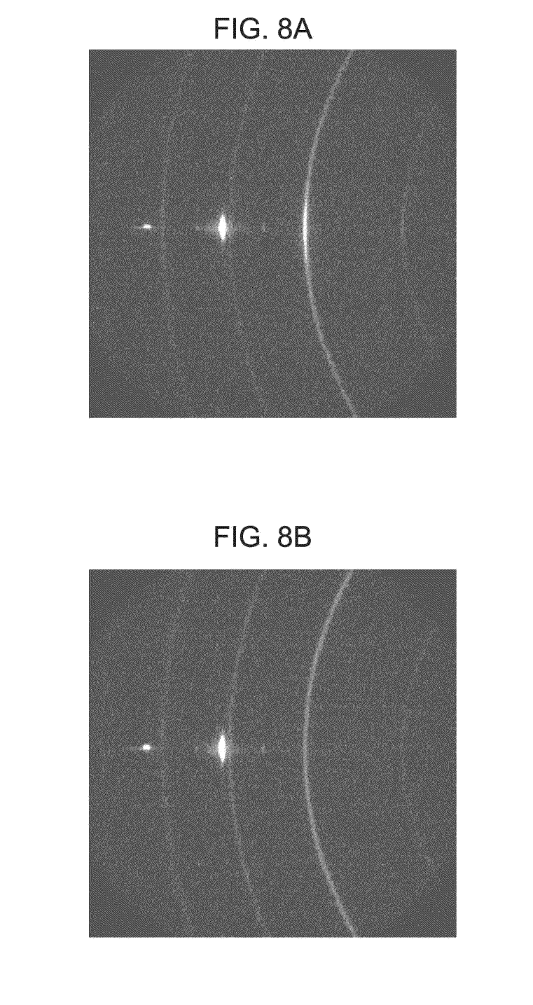

FIG. 8A illustrates a two-dimensional image obtained by performing the X-ray analysis of Example 1. FIG. 8B illustrates a two-dimensional image obtained by performing the X-ray analysis of Comparative Example. In Example 1 and Comparative Example, it was found that the peaks originating from the (100) plane, the (110) plane, and the (111) plane of the perovskite appeared at 2θ of 22.5°, 2θ of 32.0°, and 2θ of 39.3°, respectively. When focusing on the intensity of each diffraction line, due to the fact that the diffraction intensity is high around χ=0° at 2θ=32.0° in Example 1 as compared with Comparative Example, it was found that the (110) orientation degree is high. Moreover, due to the fact that the intensity is uniformly distributed not dependent on the angle of χ also in a region of 10°≦χ at 2θ=32.0°, it was found that random orientation was also co-existent in addition to the (110) orientation. In Comparative Example, due to the fact that the intensity is uniformly distributed not dependent on the angle of χ at 2θ=22.5° ((100) plane), 2θ=32.0° ((110) plane), and 2θ=39.3° ((111) plane), it was found that the orientation was random orientation.

### Evaluation of Piezoelectric Element

To Example 1 and Comparative Example, a triangular wave of a frequency of 1 kHz was applied in a room temperature atmosphere (25° C.) using a distortion measuring device (DBL1) manufactured by aixACCT, and the measurement was performed two or more times.

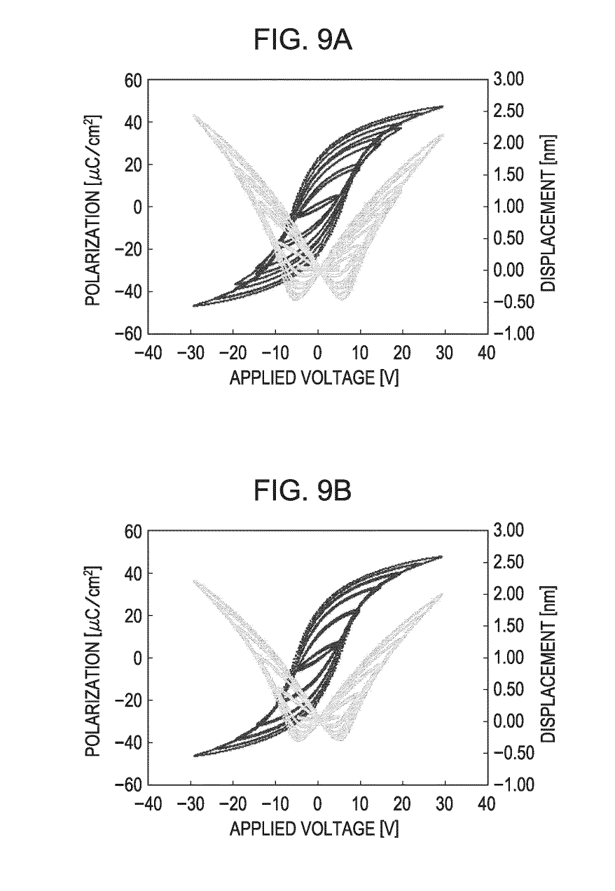

As examples of the results, the hysteresis curve and the butterfly curve of Example 1 are shown in FIG. 9A and the hysteresis curve and the butterfly curve of Comparative Example are shown in FIG. 9B. As illustrated in FIGS. 9A and 9B, the average displacement amount of the measured values was 2.4 nm in Example 1, while the average displacement amount of the measured values was 2.2 nm in Comparative Example. This shows that the displacement amount was larger and the distortion amount is higher in Example 1 than in Comparative Example.

### Index Value

From the integrated intensity in the χ direction obtained by the X-ray analysis, the index value Index₍₁₁₀₎ was calculated using Expression (5). As illustrated in FIG. 7, the index value Index₍₁₁₀₎ of Example 1 was 2.1, while the index value Index₍₁₁₀₎ of Comparative Example was 1.1. This shows that the index value Index₍₁₁₀₎ of each of Example 1 and Comparative Example is a value according to the degree of orientation of the (110) plane. More specifically, the distortion amount increased in Example 1 in which Index₍₁₁₀₎≦2.0 was established.

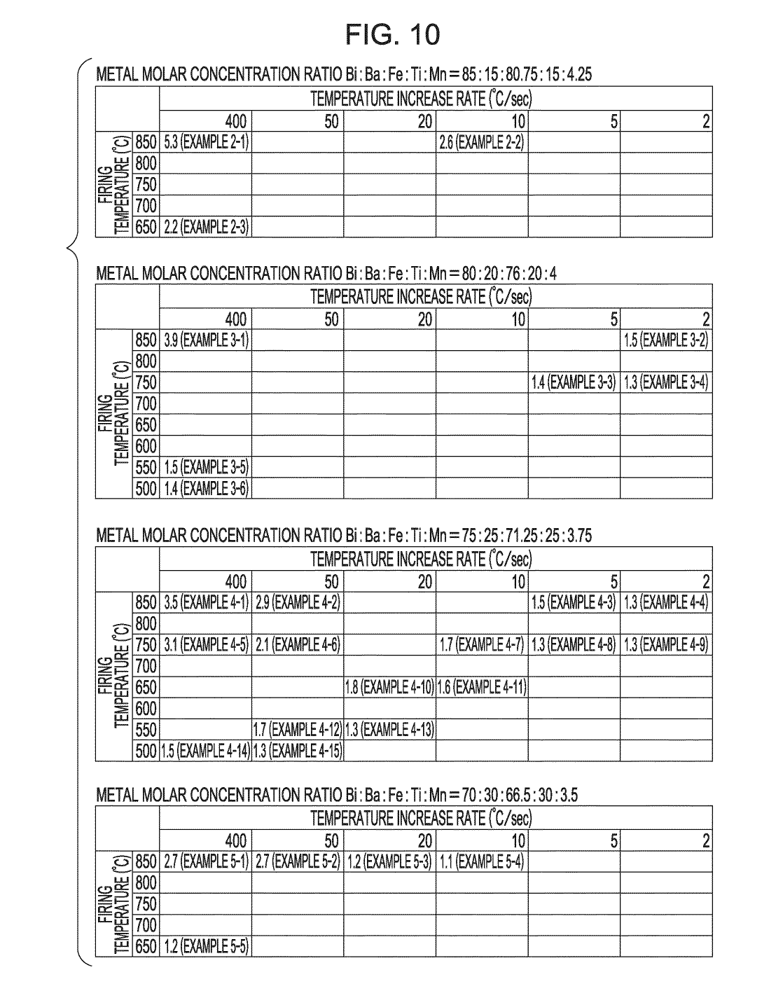

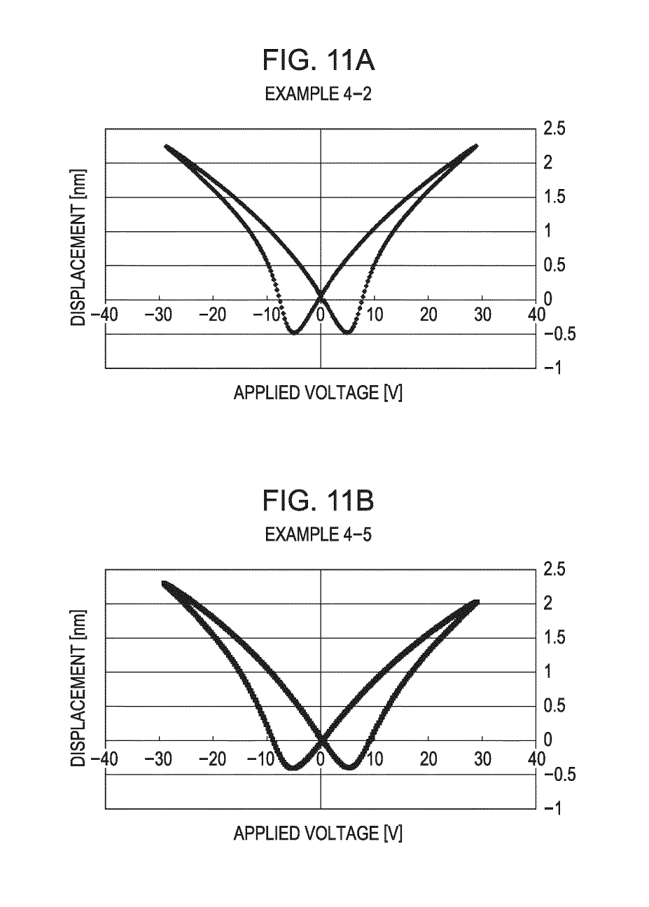

FIG. 10 is a diagram including tables showing changes in the index value Index₍₁₁₀₎ when changing the conditions for forming the piezoelectric elements. FIGS. 11A and 11B are views showing the butterfly curves of Example 4-2 and Example 4-5.

In Examples 2 to 5, piezoelectric elements were produced under the same conditions as those of Example 1, except changing the molar concentration ratio of metals of the precursor solution, the firing temperature, and the temperature increase rate. For convenience, in each of Examples 2 to 5, Examples in which the precursor solution of the same metal molar concentration ratio was used but the firing temperature and the firing rate were changed are distinguished by giving identifiers to the Examples. For example, although the molar concentration ratio of metallic elements contained in the precursor solutions is the same but the combination of the firing temperature and the temperature increase rate are different between Example 2-1 and Example 2-2.

Specifically, as Example 2, the metal molar concentration ratio of the precursor solution was set to Bi:Ba:Fe:Ti:Mn=85:15:80.75:15:4.25. As Example 3, the metal molar concentration ratio of precursor solution was set to Bi:Ba:Fe:Ti:Mn=80:20:76:20:4. As Example 4, the molar concentration ratio of metals of the precursor solution was set to Bi:Ba:Fe:Ti:Mn=75:25:71.25:25:3.75. As Example 5, the molar concentration ratio of metals of the precursor solution was set to Bi:Ba:Fe:Ti:Mn=70:30:66.5:30:3.5.

In each of Examples 2 to 5 produced as described above, it was found that the distortion amount increased in Examples in which the index value Index₍₁₁₀₎ shown in FIG. 10 was 2.0 or higher. As an example, as illustrated in FIGS. 11A and 11B, the average displacement amount of Example 4-2 (Index₍₁₁₀₎=2.9) is 2.7 nm and the average displacement amount of Example 4-5 (Index₍₁₁₀₎=3.1) is 2.5 nm. In both Examples, the distortion amount was high.

This shows that when the molar concentration ratio of Bi and Ba in the precursor solutions was 85:15 to 70:30 and the temperature increase rate was 50° C./sec or higher, the index value was 2.0 or more. Moreover, it was found that when the molar concentration ratio of Bi and Ba in the precursor solutions was in the range of 80:20 to 75:25, the firing temperature was 750° C., and the temperature increase rate was 50° C./sec or higher, the distortion amount is increased.

### Application and Others:

For the invention, various modifications are acceptable.

Although the individual piezoelectric body is provided for each pressure generating chamber in the embodiments described above, it is also possible to provide a piezoelectric body common to the plurality of pressure generating chambers and provide the individual electrode for each pressure generating chamber.

Although a part of the reservoir is formed in the flow path formation substrate in the embodiments described above, it is also possible to form a reservoir in a member different from the flow path formation substrate.

Although the upper side of the piezoelectric element is covered with the piezoelectric element holding portion in the embodiments described above, it is also possible to open the upper side of the piezoelectric element to the atmosphere.

Although the pressure generating chamber was provided on the side opposite to the piezoelectric element with the diaphragm interposed therebetween in the embodiments described above, it is also possible to provide the pressure generating chamber on the side of the piezoelectric element. For example, when a space surrounded by the fixed plates and the piezoelectric elements is formed, the space can be used as the pressure generating chamber.

The liquid discharged from the liquid ejecting head may be a material which can be discharged from the liquid ejecting head and includes fluids, such as a solution in which a dye and the like is dissolved in a solvent and a sol in which solid particles, such as pigments and metal particles, are dispersed in a dispersion medium. Such fluids include ink, a liquid crystal, and the like. The liquid ejecting head can be mounted on an image recording apparatus, such as a printer, an apparatus for manufacturing color filters of a liquid crystal display and the like, an apparatus for manufacturing electrodes of an organic EL display and the like, a biochip manufacturing apparatus, and the like.

The laminated ceramics manufactured by the manufacturing method described above can be suitably used for forming ferroelectric thin films of a ferroelectric device, a pyroelectric device, a piezoelectric device, and an optical filter. Mentioned as the ferroelectric device are a ferroelectric random-access memory (FeRAM), a ferroelectric transistor (FeFET), and the like. Mentioned as the pyroelectric device are a temperature sensor, an infrared ray detector, a temperature-electricity converter, and the like. Mentioned as the piezoelectric device are a fluid discharging device, an ultrasonic motor, an acceleration meter, a pressure-electricity converter, and the like. Mentioned as the optical filter are a filter of blocking harmful rays, such as infrared rays, an optical filter utilizing the photonic crystal effect by quantum dot formation, and an optical filter utilizing an optical interference of a thin film.

As described above, the invention can provide a technique for increasing the performance of a piezoelectric element, a liquid ejecting head, and a liquid ejecting apparatus containing a lead-free piezoelectric material or a piezoelectric material in which the lead content is reduced and the like in various aspects.

Moreover, a configuration in which the components disclosed in the embodiments and the modifications described above are replaced by each other or the combination is changed, a configuration in which the components disclosed in known techniques, the embodiments, and the modifications described above are replaced by each other or the combination is changed, and the like can be carried out. The invention includes the configurations and the like.

What is claimed is:

1. A liquid ejecting head, comprising:
a pressure generating chamber communicating with a nozzle opening; and
a piezoelectric element having a piezoelectric layer and electrodes, wherein
the piezoelectric layer is formed with a perovskite type oxide at least containing Bi, Ba, Fe, and Ti, and
when, in 2θ-θ measurement using a two-dimensional detector, an angle formed by a plane including an incident X-ray, a sample, and a center position of the two-dimensional detector and a diffraction line diffracted from the sample is defined as χ and when, in a scattering intensity of the diffraction line obtained by measuring the piezoelectric layer,
an integrated intensity in a range of 0°≦χ≦10° and 31°≦2θ≦33° is defined as I₁, and
an integrated intensity in a range of 10°≦χ≦20° and 31°≦2θ≦33° is defined as I₂,
I₁/I₂ is 2.0 or more.

2. The liquid ejecting head according to claim 1, wherein the electrodes contain Pt or Ir.

3. The liquid ejecting head according to claim 1, wherein the integrated intensity is obtained by integrating diffraction lines detected per unit time at an angle χ.

4. A liquid ejecting apparatus, comprising the liquid ejecting head according to claim 1.

5. A piezoelectric element, comprising:
a piezoelectric layer; and
electrodes, wherein
the piezoelectric layer is formed with a perovskite type oxide at least containing Bi, Ba, Fe, and Ti, and
when, in 2θ-θ measurement using a two-dimensional detector, an angle formed by a plane including an incident X-ray, a sample, and a center position of the two-dimensional detector and a diffraction line diffracted from the sample is defined as χ and when, in a scattering intensity of a diffraction line obtained by measuring the piezoelectric layer,
an integrated intensity in a range of 0°≦χ≦10° and 31°≦2θ≦33° is defined as I₁, and
an integrated intensity in a range of 10°≦χ≦20° and 31°≦2θ≦33° is I₂,
I₁/I₂ is 2.0 or more.
